(19) United States
(12) Patent Application Publication
(10) Pub. No.: US 2009/0029485 A1
(43) Pub. Date: Jan. 29, 2009

(54) MANUFACTURING METHOD OF SEMICONDUCTOR DEVICE

(75) Inventor: Wensheng WANG, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/240,005

(22) Filed: Sep. 29, 2008

Related U.S. Application Data
(63) Continuation of application No. PCT/JP2006/306651, filed on Mar. 30, 2006.

(51) Int. Cl. H01L 21/02

(52) U.S. Cl. 438/3; 257/E21.009

(57) ABSTRACT

A capacitor in which a ferroelectric film (4) is held between a lower electrode (3) and an upper electrode (5) is formed above a conductive plug (1), with a conductive base structure (2) interposed therebetween. A hard mask (6) used in patterning the conductive base structure (2) is formed over the upper electrode (5). A protective film (7) covering at least an exposed portion of the ferroelectric film (4) is formed and then heat treatment is applied to the ferroelectric film (4) in an oxygen gas atmosphere. This prevents elements constituting the ferroelectric film (4) from being released to the outside at the time of the heat treatment by thus forming the protective film (7) before applying the heat treatment to the ferroelectric film (4). Further, oxygen penetration into the conductive plug (1) is blocked by applying the heat treatment in the state where the conductive base structure (2) is not patterned.

### CROSS-REFERENCE TO RELATED APPLICATIONS

This application is a Continuation of International Application No. PCT/JP2006/306651, with an international filing date of Mar. 30, 2006, which designating the United States of America, the entire contents of which are incorporated herein by reference.

### FIELD

The present embodiment relates to a manufacturing method of a semiconductor device having a ferroelectric capacitor.

### BACKGROUND

In recent years, with development of digital technology, there has been a growing trend to process or store high-volume data at a high speed. Therefore, enhancement of integration density and performance of semiconductor devices which are used in electronic equipment are required.

Thus, with regard to a semiconductor device, in order to realize high integration density of, for example, a DRAM, the technique of using a ferroelectric material and a high dielectric material as a capacity insulating film of a capacitor element (capacitor) configuring the DRAM, instead of a silicon oxide and a silicon nitride which have been conventionally used, starts to be researched and developed.

Further, in order to realize a nonvolatile RAM capable of a write operation and a read operation at a lower voltage at a high speed, the technique of using a ferroelectric substance having a spontaneous polarization characteristic as a capacity insulating film is actively researched and developed. Such a semiconductor memory device is called a ferroelectric memory (FeRAM: Ferroelectric Random Access Memory).

A ferroelectric memory includes a ferroelectric capacitor which is configured by a ferroelectric film being held between a pair of electrodes as a capacity insulating film. In the ferroelectric memory, information is stored by using a hysteresis characteristic of the ferroelectric film.

The ferroelectric film causes polarization in accordance with an applied voltage between the electrodes, and has the spontaneous polarization characteristic even after the applied voltage is removed. Further, if the polarity of the applied voltage is reversed, the polarity of the spontaneous polarization of the ferroelectric film is also reversed. Accordingly, if the spontaneous polarization is detected, the information can be read. A ferroelectric memory operates at a low voltage as compared with a flash memory, and is capable of a write operation at a high speed with a reduced power.

Ferroelectric memories are broadly divided into a planar type and a stack type in accordance with the structures. The planar type ferroelectric memory which is the former has the structure in which electrical connection of the upper electrode and the lower electrode of the ferroelectric capacitor is taken from above. The stack type ferroelectric memory which is the latter has the structure in which electrical connection of the upper electrode of the ferroelectric capacitor is taken from above, and electrical connection of the lower electrode is taken through the conductive plug located below.

Recently, in a ferroelectric memory, higher integration density and higher performance have been also required as in the other semiconductor devices, and further miniaturization of memory cells will be required in future. It is known that adoption of the stack type structure instead of the planar type structure is effective for miniaturization of the memory cells.

Further, a ferroelectric film, which is the capacitor film of a ferroelectric capacitor, is required to have an excellent ferroelectric characteristic without degradation of crystallinity. However, a ferroelectric film undergoes a physical damage when an upper electrode is deposited on the ferroelectric film by using a sputtering method or the like, and when the ferroelectric film is patterned by etching. As a result, a part of the crystal structure of the ferroelectric film is broken, and the ferroelectric film characteristic is degraded.

Thus, in the manufacturing method of the conventional stack type ferroelectric memory, the ferroelectric capacitor is formed by patterning the upper electrode film, the ferroelectric film, the lower electric film and the like, and thereafter, annealing treatment is performed in the atmosphere of oxygen gas for the purpose of recovering the crystal structure of the ferroelectric film.

However, in the case of a stack type ferroelectric memory, the ferroelectric capacitor is formed by performing etching by one operation for the respective films formed on the conductive plug, and therefore, if annealing treatment is performed in the aforementioned atmosphere of oxygen gas after formation of the ferroelectric capacitor, there arises the problem that oxygen penetrates into the conductive plug through the interface of the interlayer insulating film, and the conductive plug is oxidized. Oxidation of the conductive plug becomes the factor that increases the wiring resistance.

In order to overcome the trouble, Patent Document 1 described as follows discloses the art of performing annealing treatment in the above described atmosphere of oxygen gas in the state where the films under the lower electrode are left without being patterned at the time of patterning of the ferroelectric capacitor.

Patent Document 1: Japanese Patent Application Laid-open No. 2004-356464

However, in the manufacturing method of the stack type ferroelectric memory of Patent Document 1, oxidation of the conductive plug can be avoided, but there is the problem that at the time of annealing treatment which is performed for the purpose of recovery of the crystal structure of the ferroelectric film, part of the constituent element (for example, Pb when the ferroelectric film is lead zirconate titanate (PZT)) is released, and a number of voids are formed in the ferroelectric film. Such a defect of the ferroelectric film which is the capacitor film of a ferroelectric memory becomes the factor that reduces the switching characteristic of the ferroelectric capacitor.

Specifically, in a recent stack type ferroelectric memory, it has been difficult to form the capacitor film with a dense film without a void without oxidizing the conductive plug, when performing thermal treatment for the purpose of recovery of the crystal structure of the capacitor film.

### SUMMARY

It is an aspect of the embodiments discussed herein to provide a manufacturing method of a semiconductor device, including: forming a conductive plug above a semiconductor substrate; forming a conductive base structure over the conductive plug; forming a capacitor with a capacitor film held between a lower electrode and an upper electrode, over the conductive base structure; forming a mask used when patterning the conductive base structure, above the upper electrode; forming a protective film covering at least an exposed portion of the capacitor film after forming the mask; and applying heat treatment to the capacitor film in an oxidizing gas atmosphere in a state where the protective film is formed.

Additional objects and advantages of the invention will be set forth in part in the description which follows, and in part will be obvious from the description, or may be learned by practice of the invention. The object and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF DRAWINGS

FIG. 1A is a schematic view for explaining a manufacturing method of a ferroelectric memory (semiconductor device) according to the present embodiment;

FIG. 1B is a schematic view for explaining the manufacturing method of a ferroelectric memory (semiconductor device) according to the present embodiment;

FIG. 1C is a schematic view for explaining the manufacturing method of a ferroelectric memory (semiconductor device) according to the present embodiment;

FIG. 2A is a schematic sectional view showing a manufacturing method of a ferroelectric memory according to an embodiment;

FIG. 2B is a schematic sectional view showing the manufacturing method of a ferroelectric memory according to the embodiment;

FIG. 2C is a schematic sectional view showing the manufacturing method of a ferroelectric memory according to the embodiment;

FIG. 3A is a schematic sectional view showing the manufacturing method of a ferroelectric memory according to the embodiment;

FIG. 3B is a schematic sectional view showing the manufacturing method of a ferroelectric memory according to the embodiment;

FIG. 3C is a schematic sectional view showing the manufacturing method of a ferroelectric memory according to the embodiment;

FIG. 4A is a schematic sectional view showing the manufacturing method of a ferroelectric memory according to the embodiment;

FIG. 4B is a schematic sectional view showing the manufacturing method of a ferroelectric memory according to the embodiment;

FIG. 4C is a schematic sectional view showing the manufacturing method of a ferroelectric memory according to the embodiment;

FIG. 5A is a schematic sectional view showing the manufacturing method of a ferroelectric memory according to the embodiment;

FIG. 5B is a schematic sectional view showing the manufacturing method of a ferroelectric memory according to the embodiment;

FIG. 5C is a schematic sectional view showing the manufacturing method of a ferroelectric memory according to the embodiment;

FIG. 6A is a schematic sectional view showing the manufacturing method of a ferroelectric memory according to the embodiment;

FIG. 6B is a schematic sectional view showing the manufacturing method of a ferroelectric memory according to the embodiment;

FIG. 6C is a schematic sectional view showing the manufacturing method of a ferroelectric memory according to the embodiment;

FIG. 7A is a schematic sectional view showing the manufacturing method of a ferroelectric memory according to the embodiment;

FIG. 7B is a schematic sectional view showing the manufacturing method of a ferroelectric memory according to the embodiment;

FIG. 7C is a schematic sectional view showing the manufacturing method of a ferroelectric memory according to the embodiment;

FIG. 8A is a schematic sectional view showing the manufacturing method of a ferroelectric memory according to the embodiment;

FIG. 8B is a schematic sectional view showing the manufacturing method of a ferroelectric memory according to the embodiment;

FIG. 8C is a schematic sectional view showing the manufacturing method of a ferroelectric memory according to the embodiment;

FIG. 9A is a schematic sectional view showing the manufacturing method of a ferroelectric memory according to the embodiment;

FIG. 9B is a schematic sectional view showing the manufacturing method of a ferroelectric memory according to the embodiment;

FIG. 9C is a schematic sectional view showing the manufacturing method of a ferroelectric memory according to the embodiment;

FIG. 10A is a schematic sectional view showing a manufacturing method of a ferroelectric memory according to a modified example of the embodiment; and

FIG. 10B is a schematic sectional view showing the manufacturing method of a ferroelectric memory according to the modified example of the embodiment.

### DESCRIPTION OF EMBODIMENTS

As a result of repeating studies in order to investigate the cause of formation of a number of voids in a ferroelectric film, the present inventor has found out that it is due to the constituent elements with a high vapor pressure being released to an outside from the exposed portion of the ferroelectric film at the time of annealing treatment in the atmosphere of oxygen gas.

From this point, the present inventor considered that in order to make the ferroelectric film a dense film, it is necessary to inhibit release of the elements constituting the ferroelectric film to an outside when performing the heat treatment. The present inventor has reached the mode of the embodiment described as follows based on these views.

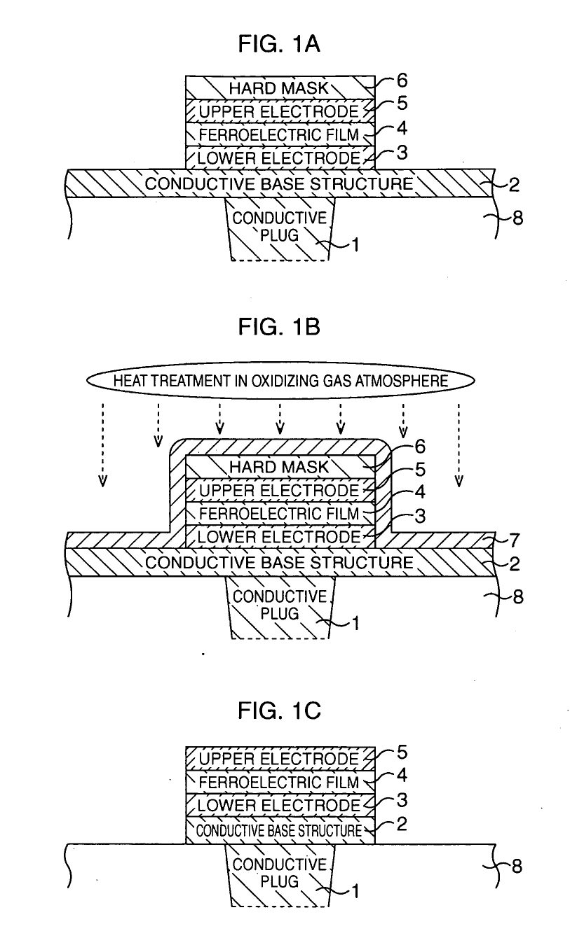

FIGS. 1A to 1C are schematic views showing a manufacturing method of a ferroelectric memory (semiconductor device) according to the present embodiment.

First, as shown in FIG. 1A, a ferroelectric capacitor having a lower electrode 3, a ferroelectric film 4 and an upper electrode film 5 above a conductive plug 1 formed on an interlayer insulating film 8 via a conductive base structure 2. Further, a hard mask 6, which is used when the conductive base structure 2 is patterned, is formed on the upper electrode 5.

Next, in the present embodiment, as shown in FIG. 1B, a protective film 7 is formed on the entire surface, and an exposed portion of the ferroelectric film 4 is covered with the protective film 7. Thereafter, in a state in which the protective film 7 is formed, heat treatment is applied to the ferroelectric film 4 in an atmosphere of oxidizing gas such as oxygen (O₂) gas. Like this, in the present embodiment, by forming the protective film 7 which covers the exposed portion of the ferroelectric film 4 in advance before the heat treatment for the ferroelectric film 4 is performed, release of the elements constituting the ferroelectric film 4 to an outside, which occurs when the heat treatment is performed, is inhibited.

Further, in the present embodiment, annealing treatment in the atmosphere of oxygen gas for the ferroelectric film 4 is performed in a state in which the conductive base structure 2 is not patterned, that is, in a state in which the conductive base structure 2 is formed on the entire surface on the conductive plug 1 and the interlayer insulating film 8. Thereby, in the present embodiment, oxygen penetration into the conductive plug 1 is blocked, and oxidization of the conductive plug is avoided.

Thereafter, as shown in FIG. 1C, the protective film 7 is removed by etching, and thereafter, patterning of the conductive base structure 2 is performed by performing etching using the hard mask 6. Subsequently, the hard mask 6 is removed, and the ferroelectric capacitor is formed.

Hereinafter, an embodiment will be described. It should be noted that a sectional structure of each memory cell of the ferroelectric memory will be described together with its manufacturing method here for convenience.

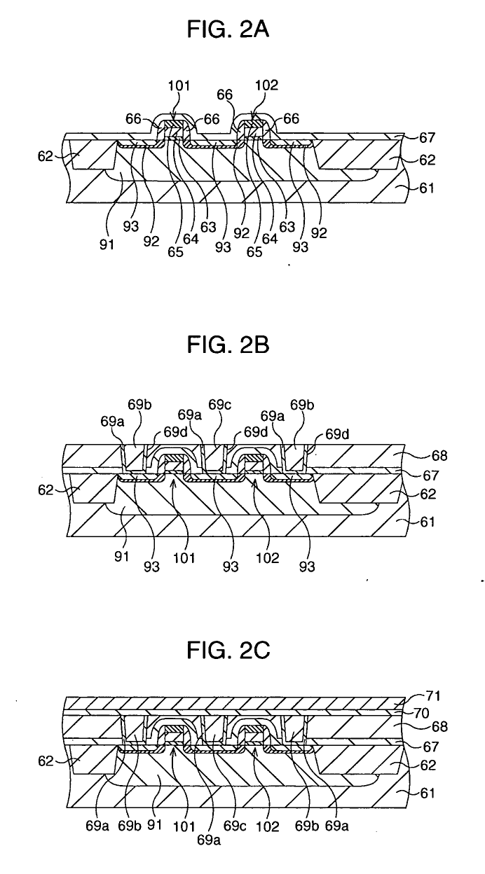

FIGS. 2A to 9C are schematic sectional views showing a manufacturing method of a ferroelectric memory (semiconductor device) according to the embodiment.

First, as shown in FIG. 2A, an element isolation structure 62 and, for example, a p-well 91 are formed in a semiconductor substrate 61, and further, above the semiconductor substrate 61, MOSFETS 101 and 102 are formed, and, for example, an SiON film (silicon oxynitride film) 67 which covers each of the MOSFETs is formed.

More specifically, first, the element isolation structure, the element isolation structure 62 by an STI (Shallow Trench Isolation) method in this case is formed in the semiconductor substrate 61 such as an Si substrate, and an element formation region is defined. In this embodiment, the element isolation structure is formed by an STI method, but the element isolation structure may be formed by, for example, an LOCOS (Local Oxidation of Silicon) method.

Subsequently, for example, boron (B) is ion-implanted in the surface of the element formation region of the semiconductor substrate 61 under the conditions of, for example, energy of 300 keV and an dose amount of 3.0×10¹³ cm⁻², and the p-well 91 is formed. Subsequently, a silicon oxide film of a thickness of about 3 nm is formed above the semiconductor substrate 61 by, for example, a thermal oxidation method. Subsequently, a polycrystalline silicon film of a thickness of about 180 nm is formed on the silicon oxide film by a CVD method. Subsequently, patterning is performed, by which the polycrystalline silicon film and the silicon oxide film are left in only the element formation region, and gate insulating films 63 constituted of the silicon oxide film, and gate electrodes 64 constituted of the polycrystalline silicon film are formed. The gate electrodes 64 configure part of a word line.

Subsequently, with the gate electrodes 64 used as masks, phosphor (P), for example, is ion-implanted in the surface of the semiconductor substrate 61 under the conditions of, for example, energy of 13 keV, a dose amount of 5.0×10¹⁴ cm⁻², and an n⁻-type low concentration diffusion layer 92 is formed. Subsequently, after an SiO₂ film of a thickness of about 300 nm is formed on the entire surface by a CVD method, anisotropic etching is performed, and the SiO₂ film is left only on side walls of the gate electrodes 64 to form side walls 66.

Subsequently, with the gate electrodes 64 and the side walls 66 as masks, arsenide (As), for example, is ion-implanted in the surface of the semiconductor substrate 61 under the conditions of, for example, energy of 10 keV and a dose amount of 5.0×10¹⁴ cm⁻², and an n⁺-type high concentration diffusion layer 93 is formed.

Subsequently, for example, a Ti film is deposited on the entire surface by, for example, a sputtering method. Thereafter, by performing heat treatment at a temperature of 400° C. to 900° C., silicide formation reaction occurs between the polycrystalline silicon film of the gate electrodes 64 and the Ti film, and a silicide layer 65 is formed on top surfaces of the gate electrodes 64.

Thereafter, the unreacted Ti film is removed by using hydrofluoric acid or the like. Thereby, the MOSFETs 101 and 102 each including the gate insulating film 63, the gate electrode 64, the silicide layer 65, the side walls 66 which are formed above the semiconductor substrate 61, and a source/drain diffusion layer, which formed beneath the surface of the semiconductor substrate 61, constituted of the low concentration diffusion layer 92 and the high concentration diffusion layer 93 are formed. In the present embodiment, formation of the n-channel type MOSFET is described as an example, but a p-channel type MOSFET may be formed. Subsequently, the SiON film 67 of a thickness of about 200 nm is formed on the entire surface by a plasma CVD method.

Next, as shown in FIG. 2B, an interlayer insulating film 68, a glue film 69a and W plugs 69b and 69c are formed.

More specifically, first, by a plasma CVD method using TEOS (tetraethyl orthosilicate) gas, a silicon oxide film of a thickness of about 1000 nm is deposited on the SiON film 67, thereafter, this is flattened by a CMP method, and the interlayer insulating film 68 constituted of the silicon oxide film is formed with a thickness of about 700 nm.

Subsequently, via holes 69d which reach the high concentration diffusion film 93 of the respective MOSFETs are each formed with a diameter of, for example, about 0.25 Ξm in the interlayer insulating film 68 and the SiON film 67. Thereafter, a Ti film of a thickness of about 30 nm and a TiN film of a thickness of about 20 nm are continuously stacked on the entire surface by, for example, a sputtering method.

Subsequently, by a CVD method, a W film of a thickness sufficient to fill each of the via holes 69d is further deposited, and thereafter, by performing flattening by polishing the W film, TiN film and Ti film until the surface of the interlayer insulating film 68 is exposed by a CMP method, the glue film 69a constituted of the Ti film and the TiN film, and the W plugs 69b and 69c are formed in the via holes 69d. The W plugs 69b and 69c are formed with a thickness of about 300 nm on the flat surface of the interlayer insulating film 68. Here, the W plug 69b connects to one of the source/drain diffusion layers of each of the MOSFETs and the W plug 69c connects to the other one.

Next, as shown in FIG. 2C, a silicon oxynitride film (SiON film) 70 of a thickness of about 130 nm is formed on the entire surface by a plasma CVD method. The silicon oxynitride film 70 becomes an oxidation preventing film which prevents oxidation of the W plugs 69b and 69c. Here, instead of the SiON film, for example, a silicon nitride film and an alumina film (Al₂O₃ film) may be formed. Subsequently, an interlayer insulating film 71 constituted of a silicon oxide film of a thickness of about 300 nm is formed on the silicon oxynitride film 70 by a plasma CVD method with TEOS as a raw material.

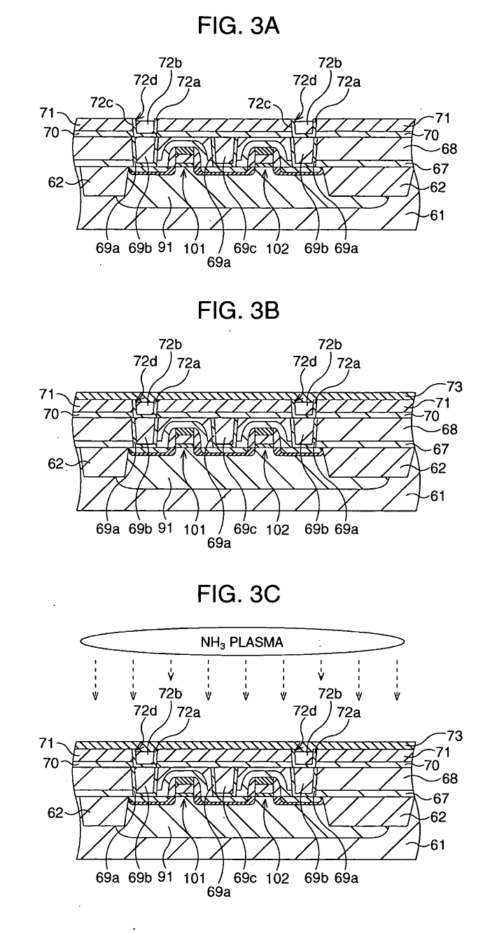

Next, as shown in FIG. 3A, a glue film 72a and W plugs 72b are formed.

More specifically, first, via holes 72c in which the surfaces of the W plugs 69b are exposed are formed in the interlayer insulating film 71 and the silicon oxynitride film 70, each with a diameter of, for example, about 0.25 μm. Thereafter, a Ti film of a thickness of about 30 nm and a TiN film of a thickness of about 20 nm are successively stacked on the entire surface by a sputtering method.

Subsequently, after a W film of a thickness sufficient to fill the via holes 72c is deposited by a CVD method, the W film, the TiN film and the Ti film are polished by a CMP method until the surface of the interlayer insulating film 71 is exposed to perform flattening, whereby the glue films 72a and the W plugs 72b are formed in the via holes 72c.

In the CMP method in this case, slurry that makes the polishing speed of the W film, TiN film and Ti film which are the objects to be polished higher than the interlayer insulating film 71 which is the base, for example, trade name SSW2000 made by Cabot Microelectronics Corporation is used. In this case, in order not to leave an unpolished portion on the interlayer insulating film 71, in the polishing by the CMP method, the polishing amount is set to be larger than the total film thickness of the W film, TiN film and Ti film. As a result, as shown in FIG. 3A, the position of the top surface of the W plug 72b becomes lower than the position of the top surface of the interlayer insulating film 71, and a recessed part (hereinafter, the recessed part will be called “recess”) 72d is formed. The depth of the recess 72d is about 20 nm to 50 nm, and is typically about 50 nm.

Thereafter, the surface of the interlayer insulating film 71 is plasma-processed in the atmosphere of NH₃ (ammonia) gas, and an NH group is caused to bond to oxygen atoms on the surface of the interlayer insulating film 71. The plasma processing using ammonia gas is performed by using, for example, a parallel plate type plasma processing apparatus having counter electrodes at a position separated by about 9 mm (350 mils) with respect to the semiconductor substrate 61, by supplying ammonia gas at a flow rate of about 350 sccm into a processing vessel held at a pressure of about 266 Pa (2.0 Torr) and at a substrate temperature of about 400° C., and supplying a high frequency of about 13.56 MHZ with a power of about 100 W to the semiconductor substrate 61 and a high frequency of about 350 kHz with a power of about 55 W to the above described counter electrodes, respectively for about 60 seconds.

Next, as shown in FIG. 3B, a TiN (titanium nitride) film 73, which fills the recess 72d and covers the top of the interlayer insulating film 71, is formed.

More specifically, first, by using, for example, a sputtering device with the distance between the semiconductor substrate 61 and the target set about 60 mm, a Ti film of a thickness of about 100 nm is formed by a sputtering method of supplying a DC power of about 2.6 kW for about seven seconds at a substrate temperature of about 20° C. under an Ar atmosphere at a pressure of about 0.15 Pa (1.1×10⁻³ Torr). Since the Ti film is formed on the interlayer insulating film 71 which is plasma-processed by using ammonia gas, the Ti atoms can freely move on the surface of the interlayer insulating film 71 without being captured by the oxygen atoms of the interlayer insulating film 71, and as a result, the Ti film becomes a self-organized Ti film in which the crystal plane is oriented along a (002) plane.

Subsequently, by applying heat treatment by RTA (Rapid Thermal Annealing) at a temperature of about 650° C. for a time of about 60 seconds to the Ti film in an nitrogen atmosphere, the TiN film 73 of a thickness of about 100 nm to be a base conductive film is formed. Here, in the TiN film 73, its crystal plane is oriented along a (111) plane. The thickness of the base conductive film is preferably about 100 nm to 300 nm, and is set at about 100 nm in the present embodiment. The base conductive film is not limited to the TiN film, and for example, a tungsten (W) film, a silicon (SiO₂) film and a copper (Cu) film can be used as the base conductive film.

In this state, in the TiN film 73, recessed portions are formed on its top surface by reflecting the shape of the recesses 72d, and this becomes the cause of degrading the crystallinity of the ferroelectric film to be formed above the TiN film 73 (orientation of the ferroelectric film becomes inhomogeneous). Thereby, the switching charge amount of the ferroelectric capacitor reduces, reliability of the ferroelectric memory reduces, and there arises the problem that a low voltage operation is difficult. Thus, in this embodiment, as shown in FIG. 3B, the top surface of the TiN film 73 is polished and flattened by a CMP method, and the above described recessed portions are removed. The slurry which is used in the CMP method is not especially limited, but in the present embodiment, the aforementioned trade name SSW2000 made by Cabot Microelectronics Corporation is used.

A variation occurs in the thickness of the flattened TiN film 73 on the interlayer insulating film 71 within the plane of the semiconductor substrate 61 and among a plurality of semiconductor substrates due to a polishing error. In consideration of the variation, in the present embodiment, the polishing time by the CMP method is controlled, and the target value of the thickness after flattening is set about 50 nm to 100 nm. In the present embodiment, the thickness of the flattened TiN film 73 on the interlayer insulating film 71 is set at about 50 nm.

Further, after flattening by the CMP method is applied to the TiN film 73, the crystal in the vicinity of the top surface of the TiN film 73 is in a distorted state by polishing. If the lower electrode of the ferroelectric capacitor formed above is influenced by the distortion, crystallinity of the lower electrode degrades (orientation of the lower electrode becomes inhomogeneous), and ultimately, the crystallinity of the ferroelectric film formed thereon degrades (orientation of the ferroelectric film becomes inhomogeneous).

In order to avoid such a trouble, in the present embodiment, as shown in FIG. 3C, plasma processing is applied to the top surface of the TiN film 73 to which flattening is applied, in an NH₃ (ammonia) gas atmosphere. By performing the plasma processing, distortion of the crystal of the TiN film 73 is eliminated, and degradation of the crystallinity of the film (ferroelectric film and the like) to be formed above the TiN film 73 can be prevented.

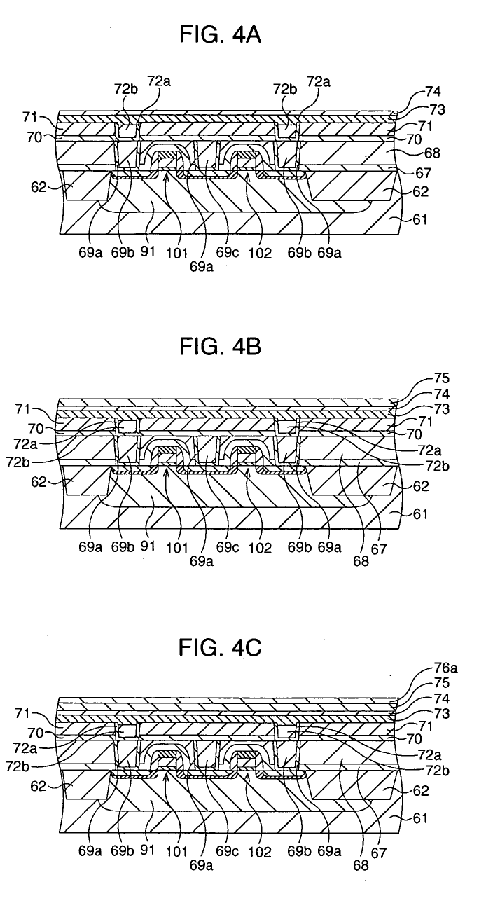

Next, as shown in FIG. 4A, a Ti film 74 of a thickness of about 20 nm is formed as a crystalline conductive adhesive film, on the TiN film 73 in which the distortion of the crystal is eliminated, by a sputtering method. Subsequently, by performing heat treatment by RTA at a temperature of about 650° C. for a time of about 60 seconds in a nitrogen atmosphere, the Ti film 74 with its crystal plane oriented along a (111) plane is formed. The Ti film 74 has the function as an adhesive film and also has a function of enhancing the orientation of the film to be formed on it by the action of the orientation of itself. The crystalline conductive adhesion film is not limited to the TiN film, and, for example, a thin precious metal film such as an Ir film and a Pt film of a thickness of about 20 nm can be used.

Next, as shown in FIG. 4B, an oxidation preventing film 75 for preventing oxidation of the W plugs 72b is formed on a Ti film 74.

More specifically, in the present embodiment, as the oxidation preventing film 75, a TiAlN film of a thickness of about 100 nm is formed on the Ti film 74 by a reactive sputtering method. For example, the reactive sputtering method in this case is carried out by using Ti and Al as an alloyed target, under the conditions of a pressure of about 253.3 Pa (1.9 Torr), a substrate temperature of 400° C. and a power of 1.0 kW in a mixture atmosphere in which Ar gas at a flow rate of about 40 sccm and nitrogen (N₂) gas at a flow rate of about 10 sccm are supplied.

In the present embodiment, the example in which the film constituted of TiAlN is applied as the oxidation preventing film 75 is shown, but the present embodiment is not limited to this, and a film including, for example, Ir or Ru can be applied. Further, in the present embodiment, the “conductive base structure” in the present embodiment is configured by the oxidation preventing film 75, the Ti film 74 which is a crystalline conductive adhesive film and the TiN film 73.

Next, as shown in FIG. 4C, an Ir film 76a of a thickness of about 100 nm is formed on the oxidation preventing film 75 by a sputtering method under the conditions of a pressure of about 0.11 Pa (8.3×10⁻⁴ Torr), a base temperature of about 500° C., and a power of 0.5 kW in an Ar atmosphere, for example. The Ir film 76a is a film to be a lower electrode of the ferroelectric capacitor.

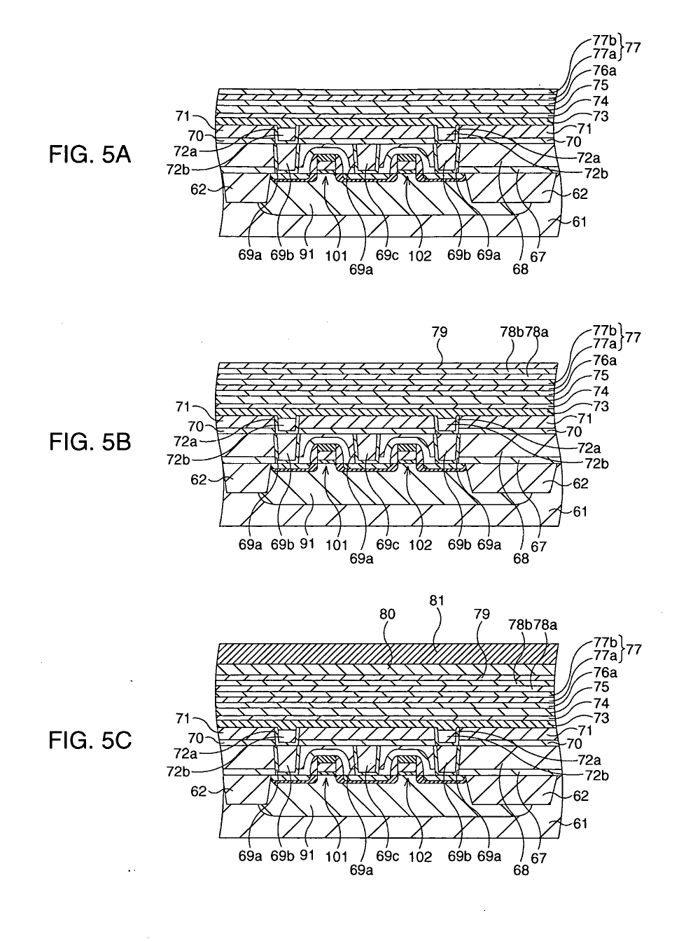

Next, as shown in FIG. 5A, a ferroelectric film 77 to be a capacitor film of the ferroelectric capacitor is formed on the Ir film 76a by an MO-CVD method. More specifically, the ferroelectric film 77 of the present embodiment is formed by a lead zirconate titanate (PZT: (Pb(Zr, Ti)O₃)) film having a two-layer structure, that is, a first PZT film 77a and a second PZT film 77b.

More specifically, first, Pb(DPM)₂, Zr(dmhd)₄ and Ti(O-iOr)₂(DPM)₂ are each dissolved into a THF (Tetra Hydro Furan: C₄H₈O) solvent at a concentration of about 0.3 mol/l, and a liquid raw material of each of Pb, Zr and Ti is formed. Further, these liquid raw materials are supplied into a vaporizer of an MO-CVD apparatus respectively at a flow rate of about 0.326 ml/minute, about 0.200 ml/minute and about 0.200 ml/minute, together with a THF solvent at a flow rate of about 0.474 ml/minute, and vaporized, and thereby, the raw material gas of Pb, Zr and Ti is formed.

Subsequently, in the MO-CVD apparatus, the raw material gas of Pb, Zr and Ti is supplied for about 620 seconds under the conditions of a pressure of about 665 Pa (5.0 Torr), and a substrate temperature of about 620° C., and thereby, the first PZT film 77a of a thickness of about 100 nm is formed on the Ir film 76a.

Subsequently, the second PZT film 77b in an amorphous state of a thickness of 1 nm to 30 nm, about 20 nm in the present embodiment is formed on the entire surface by, for example, a sputtering method. Further, when the second PZT film 77b is formed by an MO-CVD method, as the organic source for supplying lead (Pb), a material formed by dissolving Pb(DPM)₂(Pb(C₁₁H₁₉O₂)₂) in a THF solution is used. Further, as the organic source for supplying zirconium (Zr), the material formed by dissolving Zr(DMHD)₄(Zr((C₉H₁₅O₂)₄) in a THF solution is used. Further, as the organic source for supplying titanium (Ti), the material formed by dissolving Ti(O-iPr)₂(DPM)₂(Ti(C₃H₇O)₂(C₁₁H₁₉O₂)₂) in a THF solution is used.

In the present embodiment, the ferroelectric film 77 is formed by an MO-CVD method and a sputtering method, but the present embodiment is not limited to this, and the ferroelectric film 77 can be formed by, for example, a sol-gel method, a metal-organic decomposition (MOD) method, a CSD (Chemical Solution Deposition) method, a chemical vapor deposition (CVD) method or an epitaxial growth method.

Next, as shown in FIG. 5B, an IrO_{X} film 78a, an IrO_{Y} film 78b and an Ir film 79 are sequentially formed on the second PZT film 77b. In this case, the IrO_{X} film 78a functions as a lower layer film of the upper electrode, and the IrO_{Y} film 78b functions as an upper layer film of the upper electrodes.

On formation of the IrO_{X} film 78a, first, an IrO_{X} film which is crystallized is formed with an thickness of about 10 nm to 75 nm, about 50 nm in the present embodiment at the time of deposition by a sputtering method. As the sputtering conditions on this occasion, the conditions under which oxidation of iridium occurs are set, for example, the deposition temperature is set at about 20° C. to 400° C., at about 300° C. in the present embodiment, Ar and O₂ are used as deposition gas and Ar and O₂ are supplied each at a flow rate of about 100 sccm, and the power at the time of sputtering is set at about 1 kW to 2 kW. In this case, partial pressure of O₂ gas with respect to the pressure of O₂ gas and Ar gas constituting the deposition gas is preferably set at about 10% to 60%.

Thereafter, heat treatment by RTA is performed for about 60 seconds in an atmosphere in which oxygen is supplied at a flow rate of about 20 sccm and Ar is supplied at a flow rate of about 1980 sccm at a temperature of about 725° C. The heat treatment completely crystallizes the ferroelectric film 77 (second PZT film 77b) to compensate oxygen deficiency and recovers a plasma damage of the IrOₓ film 78a at the same time. The heat treatment by RTA is preferably performed at a temperature of about 650° C. to 750° C., with an oxygen content in the atmosphere at the time of heat treatment being set at 1% to 50%.

Subsequently, the IrO_{Y} film 78b is formed with a thickness of about 100 nm to 300 nm, more specifically, about 200 nm in the present embodiment on IrO_{X} film 78a by a sputtering method under the conditions of a pressure of about 0.8 Pa (6.0×10⁻³ Torr), a power of about 1.0 kW, and a deposition time of about 79 seconds in an Ar atmosphere, for example. In the present embodiment, in order to suppress deterioration in the process, the IrO_{Y} film 78b of the composition close to the stoichiometric composition of IrO₂ is applied to avoid occurrence of catalytic action for hydrogen. Thereby, the problem of the ferroelectric film 77 being reduced by hydrogen radicals is suppressed, and resistance against hydrogen of the ferroelectric capacitor is enhanced.

Subsequently, an Ir film 79 of a thickness of about 100 nm is formed on the IrO_{Y} film 78b by a sputtering method under the conditions of a pressure of about 1.0 Pa (7.5×10⁻³ Torr) and a power of about 1.0 kW in an Ar atmosphere, for example. The Ir film 79 functions as a hydrogen diffusion preventing film which prevents penetration of hydrogen, which occurs at the time of formation of wiring layers and the like, into the ferroelectric film 77. As the hydrogen diffusion preventing film, a Pt film and an SrRuO₃ film can be used other than this.

Next, after back surface cleaning of the semiconductor substrate 61 is performed, a TiN film 80 and a silicon oxide film 81 are sequentially formed on the Ir film 79 as shown in FIG. 5C. The TiN film 80 and the silicon oxide film 81 become hard masks at the time of formation of the ferroelectric capacitor.

Here, on formation of the TiN film 80, for example, a sputtering method is used. Further, on formation of the silicon oxide film 81, for example, a CVD method using TEOS gas is used.

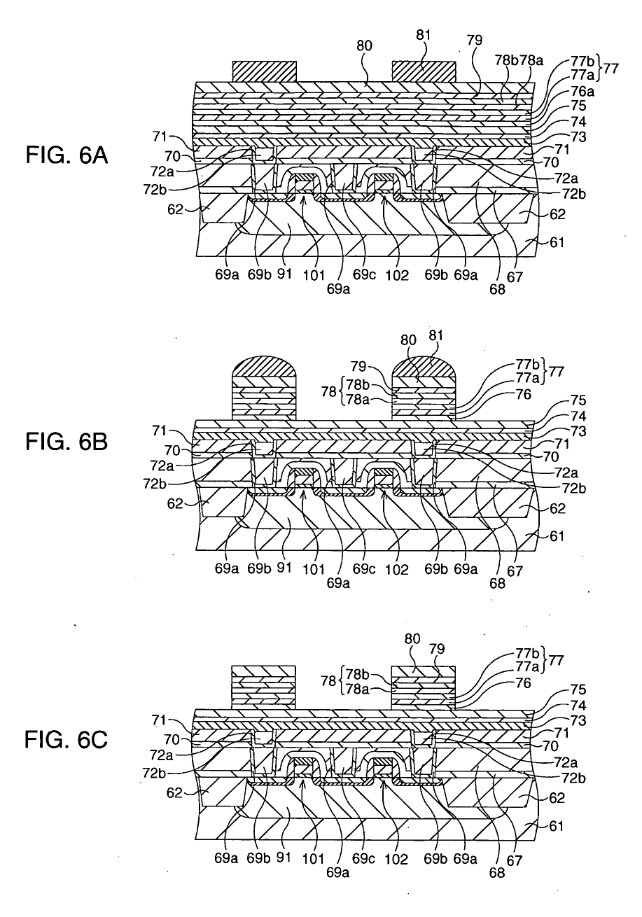

Next, as shown in FIG. 6A, the silicon oxide film 81 is patterned to cover only a ferroelectric capacitor formation region. Thereafter, the TiN film 80 is etched with the silicon oxide film 81 as a mask, and a hard mask constituted of the silicon oxide film 81 which covers only the ferroelectric capacitor formation region and the TiN film 80 is formed.

Next, as shown in FIG. 6B, the Ir film 79, the IrO_{Y} film 78b, the IrO_{X} film 78a and the second PZT film 77b, the first PZT film 77a and the Ir film 76a in the region which is not covered with the hard mask are removed by plasma etching using mixture gas of HBr, O₂, Ar and C₄F₈ as etching gas. Thereby, the ferroelectric capacitor having the upper electrode 78 constituted of the IrO_{X} film 78a and the IrO_{Y} film 78b, the ferroelectric film 77 constituted of the first PZT film 77a and the second PZT film 77b, and the lower electrode 76 constituted of the Ir film 76a is formed. In the plasma etching, even after etching stops on the oxidation preventing film 75, and the plasma etching is finished, the entire surface of the semiconductor substrate 61 is covered with the oxidation preventing film 75.

In the present embodiment, the example of applying the iridium oxide film (IrO_{X} film and IrO_{Y} film) as the upper electrode 78 is shown, but the present embodiment is not limited to this, and a film including at least one kind of metal out of iridium (Ir), ruthenium (Ru), platinum (Pt), rhodium (Rh), rhenium (Re), Osmium (Os) and palladium (Pd), or a film including an oxide in the one kind of metal can be applied. For example, the upper electrode 78 may be formed by a film including a conductive oxide of SrRuO₃.

Further, as the ferroelectric film 77 of the ferroelectric capacitor, a film in which the crystal structure becomes a Bi-layer structure (for example, one selected from (Bi₁₋ₓRₓ)Ti₃O₁₂ (R is a rare earth element: 0<x<1), SrBi₂Ta₂O₉, and SrBi₄Ti₄O₁₅) or a perovskite structure can be formed. As such a ferroelectric film 77, in addition to the PZT film which is used in the present embodiment, a film expressed by a general formula ABO₃ such as PZT, SBT and BLT doped with a very small amount of at least any one of La, Ca, Sr and Si, and a Bi-layer compound can be applied.

Further, in the present embodiment, the example in which the Ir film is applied as the lower electrode 76 is shown, but the present embodiment is not limited to this, and a film including at least one kind of metal out of Ir, Ru, Pt and Pd, or a film including an oxide in the one kind of metal can be applied. In this case, a metal of a platinum group such as Pt, or a conductive oxide such as PtO, IrO_{X} and SrRuO₃ is especially preferably used.

Next, as shown in FIG. 6C, the silicon oxide film 81 is removed by dry etching or wet etching.

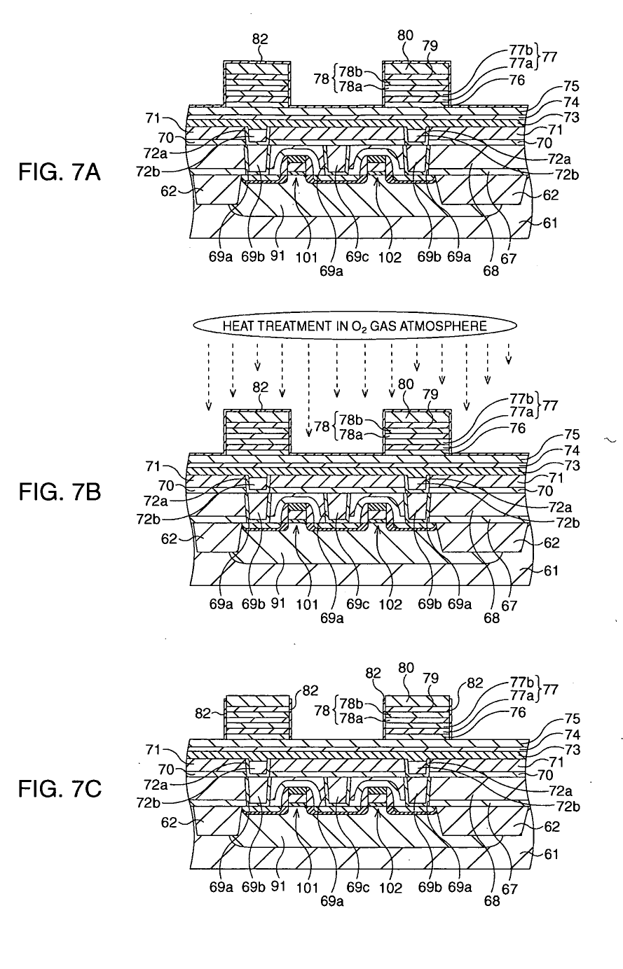

Next, as shown in FIG. 7A, a protective film 82 of a thickness of about 20 nm to 50 nm is formed on the entire surface by a sputtering method. More specifically, in the present embodiment, an alumina film (Al₂O₃ film) is formed as the protective film 82. When the protective film 82 is formed by a sputtering method, the protective film 82 is desirably formed with a thickness of about 20 nm to 50 nm as described above. If the thickness is less than 20 nm, it is difficult to cover the side surface of the ferroelectric capacitor reliably with the protective film 82, and if the thickness exceeds 50 nm, a problem occurs to through-put when the protective film 82 is worked in the post process.

Further, as the method for depositing the protective film 82, an MO-CVD method, and an ALD (Atomic Layer Dielectric) method can be applied other than a sputtering method. When the protective film 82 is formed by an MO-CVD method and an ALD method, the protective film 82 is desirably formed with a thickness of about 1 nm to 20 nm, and with the MO-CVD method and the ALD method, the side surface of the ferroelectric capacitor can be reliably covered with the protective film 82 with such a film thickness. Further, when the thickness of the protective film 82 exceeds 20 nm in this case, the protective film barriers oxygen at the time of the next recovery annealing for the ferroelectric film 77, and it becomes difficult to recover the damage of the ferroelectric film 77. The protective film 82 can be formed by a sputtering method, an MO-CVD method, or an ALD method as described above, and as the range of the film thickness with which the protective film 82 can be formed is about 1 nm to 50 nm.

An Al₂O₃ film which configures the protective film 82 is excellent in the function of inhibiting permeation of reducing substances such as hydrogen and moisture, and plays a role of preventing the ferroelectric film 77 from being reduced by the reducing substances and degraded in the ferroelectric characteristic.

Incidentally, the ferroelectric film 77 is in the state of oxygen deficiency by being damaged by sputtering at the time of deposition of the film formed above the ferroelectric film 77, etching when patterning is performed, and the like, and the ferroelectric characteristic is degraded.

Thus, in the present embodiment, as shown in FIG. 7B, for the purpose of recovering the damage of the ferroelectric film 77, heat treatment (recovery annealing) is applied to the ferroelectric film 77 in an atmosphere containing oxygen gas. The condition of the recovery annealing is a substrate temperature of 550° C. to 700° C. in a furnace. This is because when the substrate temperature is lower than 550° C., there arises a problem of being unable to recover the damage of the ferroelectric film 77 completely, and when the substrate temperature exceeds 700° C., the damage of the ferroelectric film 77 can be recovered, but part of the elements constituting the ferroelectric film 77 vaporizes, whereby the problem of Pb deficiency and the like occurs to the ferroelectric film 77, for example, and a problem of degrading the electric characteristic of the ferroelectric capacitor occurs. Further, when the ferroelectric film 77 is PZT, recovery annealing for 60 minutes is desirably performed with the substrate temperature of about 650° C. in an atmosphere containing oxygen (O₂) gas.

Thus, in the present embodiment, the protective film 82 which covers the exposed portion of the ferroelectric film 77 is formed in advance before recovery annealing is performed, and therefore, the elements (Pb since PZT is used as the ferroelectric film 77 in the present embodiment) constituting the ferroelectric film 77 can be prevented from being released to the outside.

Further, in the case of the present embodiment, even if recovery annealing is performed in an atmosphere containing oxygen gas, the oxygen preventing film 75 remains on the entire surface above the W plug 72b, and therefore, oxygen in the atmosphere of the recovery annealing is blocked by the oxygen preventing film 75, and does not reach the W plugs 72b. Thereby, oxidation of the W plugs 72b which are very easily oxidized can be prevented, occurrence of a contact failure can be reduced, and yield of the semiconductor device can be enhanced.

In addition, in the present embodiment, the TiN film 73 to which flattening by a CMP method is applied is formed on the W plug 72b. Therefore, formation of a recessed portion due to the recess 72d on the oxidation preventing film 75 can be avoided, and the oxidation preventing film 75 can be formed with a uniform thickness. Therefore, in all the portions of the oxidation preventing film 75, penetration of oxygen at the time of recovery annealing can be effectively blocked, and recovery annealing for the ferroelectric film 77 can be sufficiently performed while oxidation of the W plugs 72b is reliably prevented.

Next, as shown in FIG. 7C, etch back is applied to the protective film 82, and the protective film 82 except that on the side walls of the TiN film 80, the Ir film 79, the upper electrode 78, the ferroelectric film 77 and the lower electrode 76 is removed.

The etch back is performed under the condition of a substrate temperature of about 200° C. by supplying mixture gas of CF₄ gas at a flow rate ratio of 5% and O₂ gas at a flow rate ratio of 95% as etching gas into, for example, a down flow type plasma etching chamber, and supplying a high frequency power at a frequency of about 2.45 GHz with a power of 1400 W to the upper electrode of the chamber. Further, the etch back may be performed by wet etching with a mixture solution of, for example, H₂O₂, NH₂OH and pure water as an etching solution.

The etch back is performed anisotropically. Therefore, the protective film 82 remains on the side walls of the TiN film 80, the Ir film 79, the upper electrode 78, the ferroelectric film 77 and the lower electrode 76, and the ferroelectric film 77 can be prevented from receiving a damage by the etch back from the side surface direction.

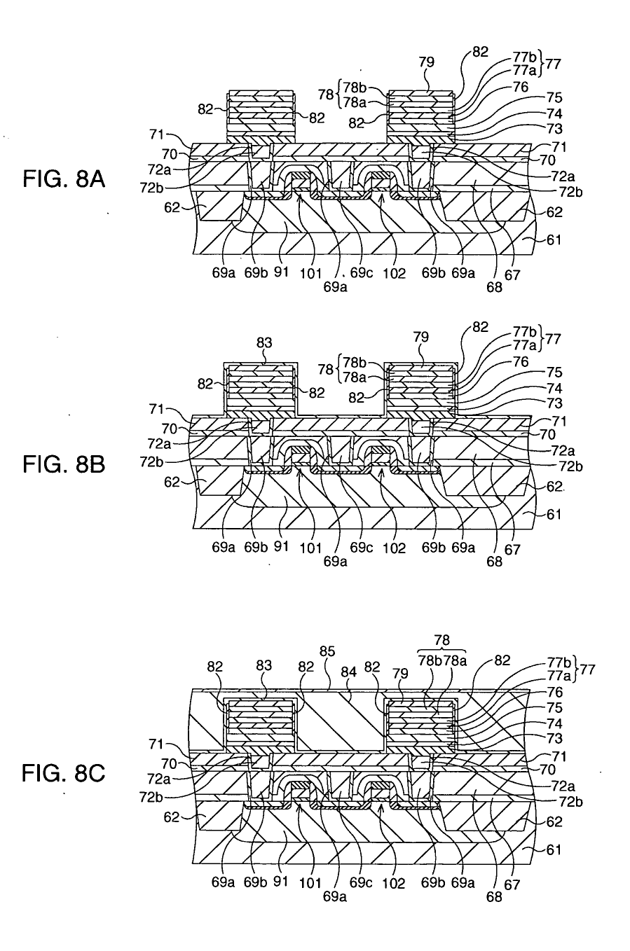

Next, by etching with the TiN film 80 as a mask, the oxidation preventing film 75, the Ti film 74 and the TiN film 73 in the region except for the ferroelectric capacitor formation regions are removed as shown in FIG. 8A. As a result of removing the TiN film 80, the protective film 82 remains on the side walls of the Ir film 79, the upper electrode 78, the ferroelectric film 77 and the lower electrode 76.

Next, as shown in FIG. 8B, an Al₂O₃ film 83 of a thickness of about 40 nm is formed on the entire surface. The Al₂O₃ film 83 functions as a hydrogen diffusion preventing film which prevents penetration of hydrogen which occurs at the time of formation of a wiring layer and the like into the ferroelectric film 77. More specifically, in the present embodiment, after an Al₂O₃ film of a thickness of about 20 nm is formed by a sputtering method first, an Al₂O₃ film of a thickness of about 20 nm is further formed by a CVD method successively, and the Al₂O₃ film 83 is formed.

Next, as shown in FIG. 8C, an interlayer insulating film 84 and an Al₂O₃ film 85 are sequentially formed on the Al₂O₃ film 83.

More specifically, first, a silicon oxide film of, for example, a thickness of about 1500 nm is deposited on the entire surface by a CVD method using, for example, plasma TEOS first. Thereafter, the silicon oxide film is flattened by a CMP method and the interlayer insulating film 84 is formed.

Here, when the silicon oxide film is formed as the interlayer insulating film 84, mixture gas of, for example, TEOS gas, oxygen gas and helium gas is used as raw material gas. As the interlayer insulating film 84, for example, an organic film or the like having insulating properties may be formed. After formation of the interlayer insulating film 84, heat treatment is performed in a plasma atmosphere which is generated by using N₂O gas, N₂ gas or the like. As a result of the heat treatment, moisture in the interlayer insulating film 84 is removed, the film quality of the interlayer insulating film 84 changes to make it difficult for water to penetrate into the interlayer insulating film 84.

Subsequently, an Al₂O₃ film 85 to be a barrier film is formed with a thickness of 20 nm to 100 nm on the interlayer insulating film 84, by, for example, a sputtering method or a CVD method. The Al₂O₃ film 85 is formed on the flattened interlayer insulating film 84, and therefore, is formed to be flat.

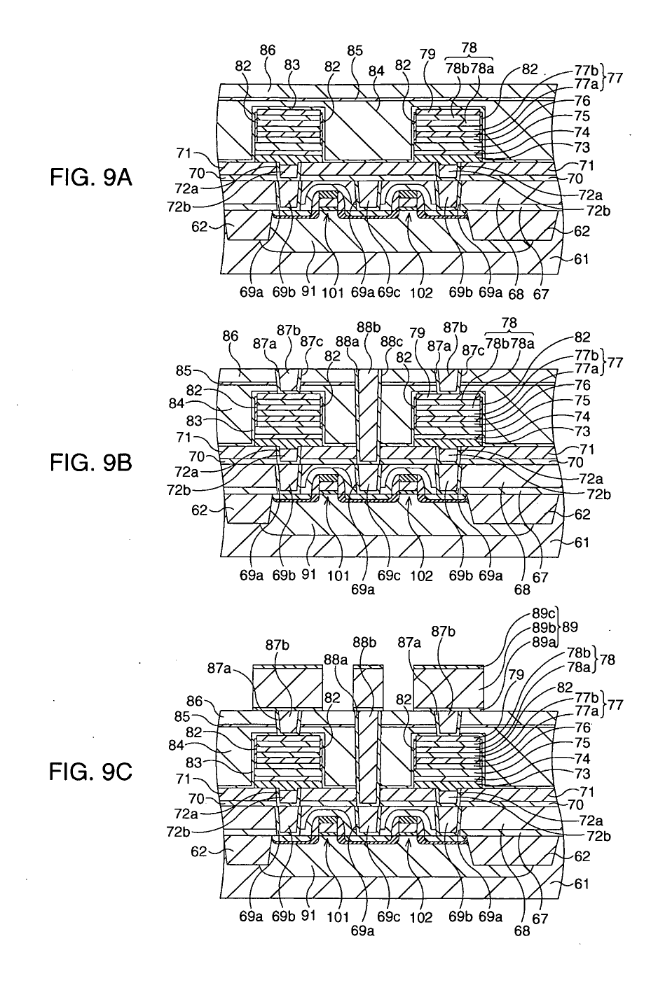

Next, as shown in FIG. 9A, a silicon oxide film is deposited on the entire surface by a CVD method using, for example, plasma TEOS, after which, the silicon oxide film is flattened by a CMP method, and an interlayer insulating film 86 of a thickness of 800 nm to 1000 nm is formed. As the interlayer insulating film 86, a silicon oxynitride film (SiON film), a silicon nitride film, or the like may be formed.

Next, as shown in FIG. 9B, glue films 87a, W plugs 87b, a glue film 88a and a W plug 88b are formed.

More specifically, first, via holes 87c for exposing the surface of the Ir film 79 which is the hydrogen diffusion preventing film in the ferroelectric capacitor are formed in the interlayer insulating film 86, the Al₂O₃ film 85, the interlayer insulating film 84 and the Al₂O₃ film 83. Subsequently, heat treatment is performed in an oxygen atmosphere at a temperature of about 550° C., the oxygen deficiency which occurs in the ferroelectric film 77 with the formation of the via holes 87c is recovered.

Thereafter, a Ti film is deposited on the entire surface by, for example, a sputtering method, and subsequently, a TiN film is continuously deposited by an MO-CVD method. In this case, carbon has to be removed from the TiN film, and therefore, the processing in plasma of mixture gas of nitrogen and hydrogen is required. However, in the present embodiment, the Ir film 79 to be the hydrogen diffusion preventing film is formed in the ferroelectric capacitor, and therefore, the problem of hydrogen penetrating into the ferroelectric film 77 and reducing the ferroelectric film 77 does not occur.

Subsequently, after a W film with a thickness sufficient to fill the via holes 87c is deposited by a CVD method, the W film, the TiN film and the Ti film are polished by a CMP method until the surface of the interlayer insulating film 86 is exposed to perform flattening, and thereby, the glue films 87a each constituted of the Ti film and the TiN film, and the W plugs 87b are formed in the via holes 87c.

Subsequently, the via hole 88c for exposing the surface of the W plug 69c is formed in the interlayer insulating film 86, the Al₂O₃ film 85, the interlayer insulating film 84, the Al₂O₃ film 83, the interlayer insulating film 71 and the silicon oxynitride film 70. Subsequently, a TiN film is deposited on the entire surface by, for example, a sputtering method. Thereafter, a W film with a thickness sufficient to fill the via hole 88c is deposited, and thereafter, the W film and the TiN film are polished until the surface of the interlayer insulating film 86 is exposed by a CMP method to perform flattening, whereby the glue film 88a constituted of the TiN film and the W plug 88b are formed in the via hole 88c. The glue film 88a can be formed as the film constituted of a stacked film of a Ti film and a TiN film by depositing the Ti film by, for example, a sputtering method, and by subsequently depositing the TiN film continuously by a MO-CVD method.

Next, as shown in FIG. 9C, a metal wiring layer 89 is formed.

More specifically, first, a Ti film of a thickness of about 60 nm, a TiN film of a thickness of about 30 nm, an AlCu alloy film of a thickness of about 360 nm, a Ti film of a thickness of about 5 nm, and a TiN film of a thickness of about 70 nm are sequentially stacked on the entire surface by, for example, a sputtering method.

Subsequently, by using a photolithography technique, the stacked film is patterned into a predetermined shape, and the metal wiring layer 89 constituted of a glue film 89a constituted of the Ti film and the TiN film, a wiring film 89b constituted of the AlCu alloy film, and a glue film 89c constituted of the Ti film and the TiN film is formed on each of the W plugs 87b and 88b.

Subsequently, after formation of an interlayer insulating film and formation of a contact plug are further performed, metal wiring layers on and after the second layer are formed, a cover film constituted of, for example, a silicon oxide film and a silicon oxynitride film is further formed, and the ferroelectric memory according to the present embodiment including the ferroelectric capacitor having the lower electrode 76, the ferroelectric film 77 and the upper electrode 78 is completed.

In the present embodiment, as the wiring layers formed on the ferroelectric capacitor, the W plugs (87b, 88b) and the wiring film 89b constituted of an AlCu alloy film are formed, but, for example, a wiring layer constituted of Al may be formed on the ferroelectric capacitor.

Further, in the present embodiment, in the recovery annealing step for the ferroelectric film 77 shown in FIG. 7B, annealing is performed in an oxygen (O₂) gas atmosphere as an example of an oxidizing gas, but the present embodiment is not limited to this, and may adopt the mode of performing annealing in an atmosphere of oxidizing gas such as, for example, a nitrogen monoxide (N₂O) and ozone (O₃). When recovery annealing for the ferroelectric film 77 is performed in an O₃ (ozone) gas atmosphere, recovery annealing can be performed at a lower temperature, for example, at a temperature of about 450° C., as compared with the case of performing annealing in an oxygen (O₂) gas atmosphere in the present embodiment. However, in this case, when the temperature becomes 550° C. or higher, O₃ is decomposed into O₂, which is not favorable.

According to the manufacturing method of a ferroelectric memory according to the embodiment, the protective film 82 which covers the exposed portion of the ferroelectric film 77 is formed in advance before recovery annealing is applied to the ferroelectric film 77 in an oxygen gas atmosphere. Therefore, the elements constituting the ferroelectric film 77 can be prevented from being released to the outside when the recovery annealing is performed, and the ferroelectric film 77 can be made a dense film. Further, the recovery annealing is performed in the state where the oxidation preventing film 75 and the like are not patterned, that is, in the state where the oxidation preventing film 75 and the like are not formed on the entire surface above the conductive plug 72b and the interlayer insulating film 71, and therefore, penetration of oxygen into the conductive plug 72b can be blocked, and oxidation of the conductive plug 72b can be avoided.

Further, in the embodiment, the TiN film 73 which is flattened by a CMP method is formed on the W plug 72b, and therefore, formation of the recessed portion due to the recess 72d on the upper layer film on it can be avoided. Thereby, the influence of the recess 72d on the ferroelectric film 77 can be shut off, and the crystallinity of the ferroelectric film 77 can be kept in a favorable state. Further, in the embodiment, plasma processing is applied to the top surface of the TiN film 73, to which flattening is applied, in an NH₃ (ammonia) gas atmosphere, and therefore, even when a distortion in the crystal of the TiN film 73 occurs as a result of flattening, the distortion in the crystal can be eliminated, and degradation of crystallinity of the film (ferroelectric film 77 and the like) formed above the TiN film 73 can be prevented.

Further, in the embodiment, the Al₂O₃ film 83 (hydrogen diffusion preventing film) is formed to cover the ferroelectric capacitor before the interlayer insulating film 84 is formed, and therefore, hydrogen which occurs at the time of formation of the interlayer insulating film 84 and the like can be prevented from penetrating into the ferroelectric film 77.

### Modified Example

Hereinafter, a modified example according to the embodiment will be described.

Concerning the modified example shown as follows, the same constituent members and the like as those disclosed in the embodiment are assigned with the same reference numerals and characters, and since the manufacturing methods of the constituent members and the like are the same as those disclosed in the embodiment, the detailed explanation of the manufacturing methods will be omitted.

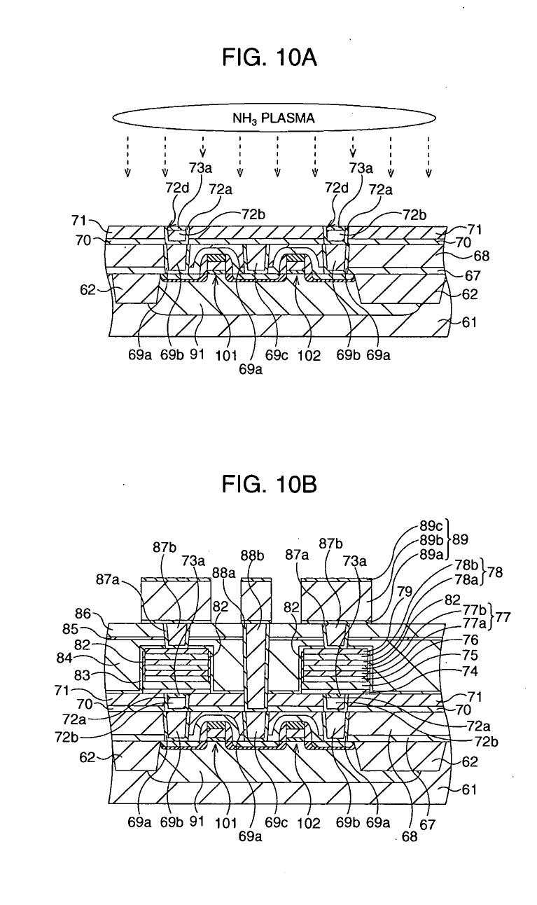

FIGS. 10A and 10B are schematic sectional views showing a manufacturing method of a ferroelectric memory (semiconductor device) according to the modified example of the embodiment.

In the modified example, the glue film 72a and the W plugs 72b are formed in the via holes 72c first through each of the steps of FIGS. 2A to 2C and FIG. 3A. On this occasion, recesses 72d are formed in the W plugs 72b.

Next, as shown in FIG. 10A, TiN films 73a are formed to fill the recesses 72d.

More specifically, first, plasma processing is applied to the surface of the interlayer insulating film 71 in an NH₃ (ammonia) gas atmosphere to cause NH groups to bond to the oxygen atoms on the surface of the interlayer insulating film 71. Subsequently, a Ti film of a thickness of about 100 nm is formed on the entire surface by, for example, a sputtering method. Thereafter, by applying heat treatment by RTA at a temperature of about 650° C. for a time of about 60 seconds to the Ti film in a nitrogen atmosphere, a TiN film of a thickness of about 100 nm to be a base conductive film is formed. The base conductive film is not limited to a TiN film, and, for example, a TiAlN film, a tungsten (W) film, a silicon (SiO₂) film and a copper (Cu) film can be used as the base conductive film.

In this state, in the TiN film, recessed portions are formed on its top surface by reflecting the recesses 72d, and this becomes the factor of degradation of crystrallinity of the ferroelectric film which is formed above the TiN film (the orientation of the ferroelectric film becomes inhomogeneous).

Thus, in this example, by performing flattening by polishing the TiN film until the surface of the interlayer insulating film 71 is exposed by a CMP method, the recessed portion formed on the TiN film is removed, and a TiN film 73a which fills the recesses 72d is formed.

Further, after flattening by the CMP method is applied to the TiN film 73a, the crystal in the vicinity of the top surface of the TiN film 73a is in a distorted state by polishing. If the lower electrode of the ferroelectric capacitor to be formed above receives the influence of the distortion, crystallinity of the lower electrode degrades (the orientation of the lower electrode becomes inhomogeneous), which ultimately leads to degradation of the crystallinity of the ferroelectric film formed thereon (the orientation of the ferroelectric film becomes inhomogeneous).

In order to avoid such a trouble, in the present embodiment, plasma processing is further applied to the top surface of the flattened TiN film 73a in the atmosphere of NH₃ (ammonia) gas, as shown in FIG. 10A. By performing the plasma processing, distortion of the crystal of the TiN film 73a is eliminated, and degradation of the crystallinity of the film (ferroelectric film and the like) which is formed above the TiN film 73a can be prevented.

Next, after the Ti film 74 shown in FIG. 4A is formed on the entire surface, each of the steps in FIGS. 4B to 9C is carried out, and thereby, the ferroelectric memory according to the modified example shown in FIG. 10B is completed.

According to the manufacturing method of a ferroelectric memory according to the modified example, the same effect as the ferroelectric memory according to the above described embodiment can be provided.

According to the present embodiment, oxidation of the conductive plugs is avoided, and a dense capacitor film can be formed. Thereby, increase in wiring resistance can be prevented, and a switching characteristic of the capacitor can be improved.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A manufacturing method of a semiconductor device, comprising:
forming a conductive plug above a semiconductor substrate;
forming a conductive base structure over the conductive plug;
forming a capacitor with a capacitor film held between a lower electrode and an upper electrode, over the conductive base structure;
forming a mask used when patterning the conductive base structure, above the upper electrode;
forming a protective film covering at least an exposed portion of the capacitor film after forming the mask; and
applying heat treatment to the capacitor film in an oxidizing gas atmosphere in a state where the protective film is formed.

2. The manufacturing method of a semiconductor device according to claim 1,
wherein the protective film is a film containing at least any one kind of an aluminum oxide, a titanium oxide and lead zirconate titanate.

3. The manufacturing method of a semiconductor device according to claim 1,
wherein the conductive base structure includes an oxidation preventing film preventing oxidation of the conductive plug.

4. The manufacturing method of a semiconductor device according to claim 1,
wherein said step of forming the conductive base structure comprises the steps of:
forming a conductive film over the conductive plug and an interlayer insulating film with the conductive plug formed therein, and
flattening a top surface of the conductive film.

5. The manufacturing method of a semiconductor device according to claim 4, further comprising the step of applying plasma processing to the top surface of the conductive film in an atmosphere of gas containing nitrogen, after flattening the top surface of the conductive film.

6. The manufacturing method of a semiconductor device according to claim 5, wherein the gas containing nitrogen is NH₃ (ammonia) gas.

7. The manufacturing method of a semiconductor device according to claim 4, wherein in said step of flattening the top surface of the conductive film, the conductive film is flattened until a surface of the interlayer insulating film is exposed.

8. The manufacturing method of a semiconductor device according to claim 1, further comprising the steps of:
leaving the protective film over only a side wall of the capacitor by etching an entire surface of the protective film, after performing the heat treatment; and
patterning the conductive base structure by using the mask after performing etching for the protective film.

9. The manufacturing method of a semiconductor device according to claim 8, further comprising the step of forming a hydrogen diffusion preventing film preventing diffusion of hydrogen to the capacitor film, after patterning the conductive base structure.

10. The manufacturing method of a semiconductor device according to claim 1, wherein said step of performing heat treatment is carried out under a condition of a temperature of the semiconductor substrate of 550° C. to 700° C.

11. The manufacturing method of a semiconductor device according to claim 1, wherein the oxidizing gas is gas including at least any one of oxygen (O₂) gas, nitrogen monoxide (N₂O) gas and ozone (O₃) gas.

12. The manufacturing method of a semiconductor device according to claim 1, wherein in said step of forming the capacitor, at least the upper electrode and the capacitor film are collectively patterned.

13. The manufacturing method of a semiconductor device according to claim 1, wherein the capacitor film is a film constituted of a ferroelectric material.

14. The manufacturing method of a semiconductor device according to claim 1, wherein the upper electrode is a film including at least any one kind of metal out of 1r (iridium), Ru (ruthenium), Pt (platinum), Rh (rhodium), Re (rhenium), Os (osmium) and Pd (palladium), or a film including an oxide in the one kind of metal.

15. The manufacturing method of a semiconductor device according to claim 1, wherein the lower electrode is a film including at least any one kind of metal out of Ir (iridium), Ru (ruthenium), Pt (platinum) and Pd (palladium), or a film including an oxide in the one kind of metal.

16. The manufacturing method of a semiconductor device according to claim 1, wherein the protective film is formed by a sputtering method, an MOCVD method or an ALD method.

17. The manufacturing method of a semiconductor device according to claim 1, wherein a film thickness of the protective film is 1 nm to 50 nm.

18. The manufacturing method of a semiconductor device according to claim 1, wherein the capacitor film forms a compound film of a perovskite structure or a compound film of a Bi-layer structure.

19. The manufacturing method of a semiconductor device according to claim 3, wherein the oxidation preventing film is formed by a conductor selected from a group constituted of TiAlN (titanium-aluminum nitride), TiAlON (titanium-aluminum oxynitride), Ir (iridium) and Ru (ruthenium).
